(19) United States
(12) Patent Application Publication
(10) Pub. No.: US 2026/0143899 A1
(43) Pub. Date: May 21, 2026

(54) ORGANIC ELECTROLUMINESCENT DEVICES

(71) Applicant: Universal Display Corporation, Ewing, NJ (US)

(72) Inventors: Michael Fusella, Lawrenceville, NJ (US); Nicholas J. Thompson, New Hope, PA (US); Haridas Mundoor, Ewing, NJ (US); Rasha Hamze, Philadelphia, PA (US)

(21) Appl. No.: 19/388,038

(22) Filed: Nov. 13, 2025

Related U.S. Application Data
(60) Provisional application No. 63/723,149, filed on Nov. 21, 2024.

(51) Int. Cl. H10K 50/115; G02B 5/00; H10K 50/165; H10K 50/19; H10K 50/852

(52) U.S. Cl. CPC H10K 50/115; G02B 5/008; H10K 50/165; H10K 50/19; H10K 50/852

(57) ABSTRACT

Embodiments of the disclosed subject matter provide a device that may include a substrate, a first electrode disposed over the substrate, and a first organic emissive layer (EML) disposed over the first electrode, with the first EML including a first emissive material. A second electrode may be disposed over the first EML. A first self-absorbing material (SAM) may be disposed in a stack with the substrate, where the SAM may include a material that transfers at least a portion of the energy from the first EML to the first SAM.

### CROSS-REFERENCE TO RELATED APPLICATIONS

This application claims priority to U.S. Patent Application Ser. No. 63/723,149, filed Nov. 21, 2024, the entire contents of which are incorporated herein by reference.

### FIELD

The present invention relates to devices and techniques for fabricating organic emissive devices, such as organic light emitting diodes, that include materials with strong absorption to absorb light generated from an organic device stack, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a device that is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more devices selected from a consumer product, an electronic component module, and/or a lighting panel.

According to an embodiment, a device may include a substrate, a first electrode disposed over the substrate, and a first organic emissive layer (EML) disposed over the first electrode, with the first EML including a first emissive material. A second electrode may be disposed over the first EML. A first self-absorbing material (SAM) may be disposed in a stack with the substrate, the first SAM may include a material that transfers at least a portion of the energy from the first EML to the first SAM. The first SAM may be disposed at a location that is below the substrate, within the substrate, and/or above the substrate.

The second electrode of the device may comprise an enhancement layer, where the enhancement layer comprises a plasmonic material that exhibits surface plasmon resonance that couples to the first emissive material.

The device may include enhancement layer comprising a plasmonic material that exhibits surface plasmon resonance that couples to the first emissive material. The plasmonic material may be capable of transferring excited state energy non-radiatively or radiatively.

The SAM may be capable of at least one of emitting light, coupling energy into a plasmon mode of the enhancement layer, and/or transferring energy to another material.

The first EML of the device may include the first SAM.

The first emissive material of the device may be the first SAM.

The first electrode of the device may be a reflective electrode, and the first SAM may be disposed over the first EML or within the first EML. The first and second electrodes may form a microcavity structure tuned for an emission spectrum of the emissive material. The first and second electrodes of the device may form a microcavity structure that is detuned away from the emission of wavelengths by an emitter in the microcavity.

The first electrode of the device may be a transparent electrode, and the first SAM may be disposed over the first EML or within the first EML. The first electrode may be transparent, and the first electrode is disposed over the first SAM. The device may further include a reflector disposed on a side of the substrate that is opposite to the first electrode. The reflector may be disposed at least 10 μm away from the first EML. The first SAM may be disposed between the reflector and the substrate.

The device may include an outcoupling layer disposed over the first SAM. The outcoupling layer may include a plasmon-to-photon outcoupling layer.

A photoluminescent quantum yield (PLQY) of the first SAM of the device may be at least 80%. A relationship between a radiative rate (kR) and a non-radiative rate (kNR) of the first SAM or the first EML of the device may be kR≥4*kNR.

The device may include a second SAM disposed over the second electrode. The first and second electrodes may form a microcavity structure tuned for an emission spectrum of the emissive material. The first emissive layer of the device may be part of a first organic light emitting diode (OLED) stack, and may include a second emissive layer that may be part of a second OLED stack, where the first emissive layer is closer to the enhancement layer than the second emissive layer, and where the first emissive layer is within a threshold distance. The first emissive material may have a total non-radiative decay rate constant

$${k}_{non - rad}^{0} ,$$

a total non-radiative decay rate constant

$${k}_{rad}^{0} ,$$

a total radiative decay rate constant due to the enhancement layer

$${k}_{non - rad}^{plasmon} ,$$

and a total radiative decay rate constant due to the enhancement layer

$${k}_{rad}^{plasmon} ,$$

where the enhancement layer may be disposed not more than the threshold distance from the first emissive material, and where the threshold distance is a distance at which

$$\frac{{k}_{rad}^{plasmon}}{{k}_{non - rad}^{plasmon}} = \frac{{k}_{rad}^{0}}{{k}_{non - rad}^{0}} .$$

The device may include a charge generation layer disposed over the first EML, and a second EML disposed above the charge generation layer, the second EML may include a second emissive material. The first EML of the device may include the first SAM. The second EML of the device may include the second SAM. At least two of the first electrode, the second electrode, and the charge generation layer may form a microcavity structure tuned or detuned for an emission spectrum of the first emissive material and/or the second emissive material.

The device may include a second SAM disposed over the first SAM and between the first electrode and the second electrode. The first and second electrodes may form a microcavity structure tuned or detuned for an emission spectrum of the emissive material.

The material of the first SAM of the device may absorb at least 1%, 5%, 10%, 25%, 50%, or 100% of light emitted by the EML. The material of the first SAM of the device may absorb greater than 0.3%, greater than 1%, greater than 3%, greater than 5%, greater than 10%, greater than 20%, greater than 50%, and/or greater than 90% of light emitted by the EML.

The SAM of the device may have at least one property of: a Stoke's shift between the absorption and emission spectra of the SAM of less than or equal to 100 nm; an extinction coefficient of a highest absorption band of the SAM that is greater than or equal to 103 M⁻¹. cm⁻¹; a poly-carbo or heterocyclic ring system comprising at least two fused rings; the SAM is doped at a concentration of greater than or equal to 0.5% by volume; the SAM is doped uniformly into the first EML and is capable of accepting energy transferred from one or more of the components of the first EML; the SAM is doped at an interface between the first EML and a blocking layer (BL) interface and is capable of accepting energy transferred from one or more of the components of the first EML or of the BL; and the SAM is doped into a transport layer (e.g., and electron transport layer (ETL) or a hole transport layer (HTL)) and is capable of accepting energy transferred from one or more of the components of the transport layer or one or more of the components of the EML.

The first SAM may comprise a self-absorbing emitter (SAE) layer that has a vertical dipole ratio (VDR) of at least one selected from a group consisting of: less than 0.33, less than 0.25, and less than 0.2.

In an embodiment, the first electrode of the device may comprise an enhancement layer, the second electrode may comprise an enhancement layer, and/or the device may comprise an enhancement layer disposed over the second electrode.

According to an embodiment, the device may be a consumer electronic device that is a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, optical communication device, and/or a sign.

### BRIEF DESCRIPTION OF THE DRAWINGS

FIG. 1 shows an organic light emitting device.

FIG. 2 shows an inverted organic light emitting device that does not have a separate electron transport layer.

FIGS. 3A-3D show emissive devices containing a self-absorption layer that may be located in the emissive layer of the device (FIGS. 3C and 3D), or may not be located in the emissive layer of the device (FIGS. 3A-3B). FIGS. 3A and 3C show devices containing a reflective layer that establishes a microcavity, whereas FIGS. 3B and 3D show devices that include a reflective layer that reflects light in the far field but is at least 10 micrometers from the OLED layers, creating an incoherent reflection, thereby avoiding microcavity effects according to embodiments of the disclosed subject matter.

FIGS. 4A-4F show a tandem OLED containing a self-absorption layer either in the emissive layer (FIGS. 4C-4F) or in a separate layer (FIGS. 4A-4B). The tandem stack may contain a reflective layer that establishes a microcavity (FIGS. 4A, 4C, 4E) or may contain a reflective layer that reflects light in the far field but is at least 10 micrometers from the OLED layers, creating an incoherent reflection, thereby avoiding microcavity effects (FIGS. 4B, 4D, 4F) according to embodiment of the disclosed subject matter.

FIG. 5 shows a plot of calculations of the cumulative plasmon in-coupling fraction as a function of the number of absorption/emission cycles in the device according to embodiments of the disclosed subject matter.

FIGS. 6A-6B show devices that include more than one SAE (self-absorbing emitter) layer. The devices may contain a reflective layer that establishes a microcavity (FIG. 6A) or may include a reflective layer that reflects light in the far field, thereby avoiding microcavity effects (FIG. 6B) according to embodiments of the disclosed subject matter.

FIGS. 7A-7B show device having an OLED that may have two SAE layers, one inside the device and one outside the device. The second SAE layer can sit either directly above the top electrode (FIG. 7A) or be part of the out-coupling scheme (FIG. 7B) according to embodiments of the disclosed subject matter.

FIG. 8A shows a tandem OLED where at least one emissive layer and SAE layer is within a threshold distance of the enhancement layer according to embodiments of the disclosed subject matter.

FIG. 8B shows a single-stack device where the EML and one or more SAE layers are within a threshold distance of the enhancement layer according to embodiments of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

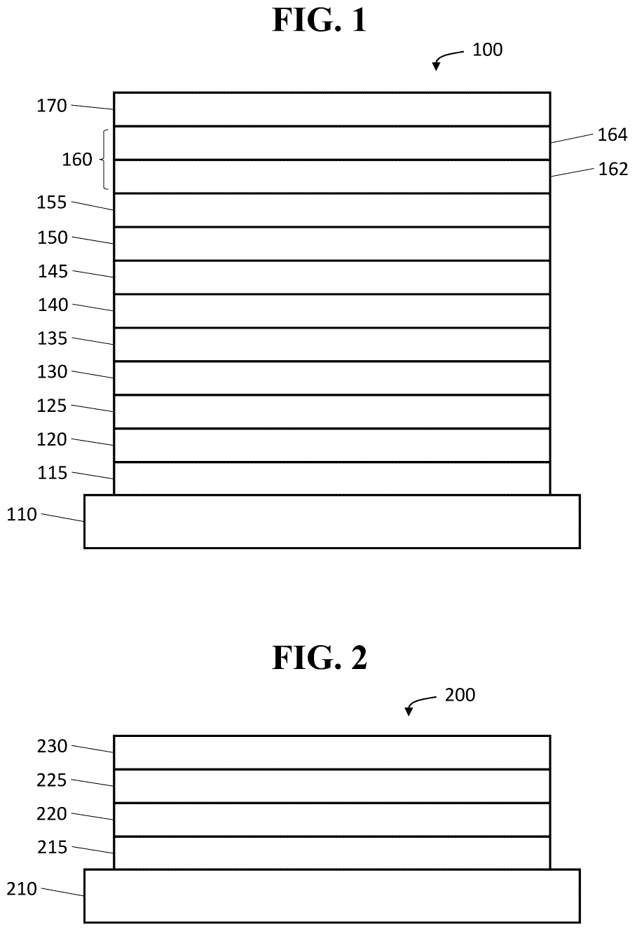

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg: Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer, as disclosed in U.S. Pat. No. 9,960,386 and incorporated by reference in its entirety. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered as photons to free space. In other embodiments, the energy is scattered or extracted from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric spacer layers can be disposed between the enhancement layer and the outcoupling layer. The plasmonic stack may include a dielectric spacer material (i.e., a dielectric spacer layer) having a refractive index selected based on a color of light emitted by the organic emissive material. In an embodiment, the dielectric spacer material (i.e., dielectric spacer layer) may be located between the enhancement layer and the nanoparticles in the plasmonic stack. In an alternative embodiment, the dielectric spacer material may be located between the two electrodes in the plasmonic stack. In yet another embodiment, the dielectric spacer material may be located on either side of either electrode, outside of the plasmonic stack. In yet another embodiment, the dielectric spacer material may be located between the enhancement layer and the outcoupling layer or may be integrated within the outcoupling layer. In some embodiments, the dielectric spacer layer may be found only in a plasmonic stack sub-pixel, only in a non-plasmonic stack sub-pixel or in both. Examples of material suitable for use in dielectric spacer layers include dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with viewing angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, optical communication device, and/or a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

The enhancement layer described above may comprise a plasmonic material exhibiting surface plasmon resonance that non-radiatively couples to the emitter material. In some embodiments, the emitter may couple to the surface plasmon modes through a nearfield interaction. In some other embodiments, the emitter may couple to the surface plasmon mode through a far-field optical interaction. The process of coupling between emitter and surface plasmon may enable transfer of excited state energy from the emitter material to non-radiative and/or radiative modes of surface plasmon polariton.

Organic light emitting devices (OLEDs) are typically designed with emitters having high photoluminescent quantum yields and materials with low absorption of the photons generated within an OLED stack. This ensures that photons generated by the radiative recombination of excitons will not be reabsorbed and will instead be emitted as light outside the device. However, conventional OLEDs are limited by the refractive index contrast between an organic layer and air that limits light extraction efficiency.

Plasmonic OLEDs incorporating one or more plasmonic enhancement layers couple excited state energy into the surface plasmon mode of a nearby enhancement layer, which can be done via near- or far-field coupling, and then convert the plasmon energy to light. In the case of a nanoparticle-based outcoupling (NPO) scheme (i.e., an outcoupling layer comprising nanoparticles), the light can be generated directly in air, circumventing the light extraction efficiency limit imposed on conventional OLEDs. Since the plasmon outcoupling efficiency has the potential to be much higher than conventional OLED extraction efficiency, it is important to maximize the amount of excited state energy that can be coupled into the plasmon mode, which can be referred to in-coupling.

A major factor limiting the plasmon in-coupling efficiency arises from the fact that excitons located a certain distance away from the enhancement layer will have a sub-unity probability of exciting a surface plasmon polariton (SPP). Practical device considerations, such as device shorting, charge balance, and the like require the emissive layer (EML) to be spaced a finite distance away from the enhancement layer. Excitons that do not form SPPs may radiatively recombine and emit a photon inside a device. Instead of having that photon escape the device or become trapped in a waveguided mode, embodiments of the disclosed subject matter provide OLED devices that include one or more materials that reabsorb emitted light and in-couple the energy into the plasmon mode, either directly or via one or more intervening materials. As used throughout, such materials may be referred to as self-absorbing materials (SAM), and layers containing SAMs may be referred to as self-absorbing layers (SAL). Emitters that absorb their own emission are referred to as self-absorbing emitters (SAE). A SAE may be a SAM that emits at least some of or all of the light it absorbs. SAMs, SALs, and/or SAEs also may absorb ambient light that enters the device, which also may be in-coupled in the same manner.

In an embodiment, the SAM and/or SAE may comprise phthalocyanines, including variants like boron subphthalocyanine chloride, boron sub-2,3-naphthalocyanine chloride, hexachlorinated boron subphthalocyanine chloride, etc., porphyrins dyes, coumarin dyes, photochromic dyes, perylene dyes, cyanine and/or squarylium dyes, dipyrromethene dyes, xanthene dyes, quinacridone, DIPYR (Dipyridamole) dyes, BODIPY (Boron-dipyrromethene) dyes, phosphors, fluorophores, thermally activated delayed fluorescent (TADF) materials, quantum dots, perovskite materials, boron di-pyrromethene, rhodamine, fluorescein, fluorescein isothiocyanate, calcein, ethidiumbromide, phycoerythrin, carboxynaphthofluorescein, hexachlorofluorescein, tetramethylrhodamine, phenylethynylpyrene or quantum confined nano crystals of cadmium selenide, cadmium sulfide, cadmium telluride, core shell cadmium selenide-zinc sulfide, core shell cadmium selenide-zinc selenide, lead sulfide, zinc selenide, etc., 2D materials such as molybdenum disulfide (MoS2), molybdenum diselenide (MoSe2), tungsten disulfide (WS2), tungsten diselenide (WSe2), among others. In a preferred embodiment, SAM and/or SAE comprises a material that has a peak absorption coefficient within the desired filtering range greater than 10⁴ cm⁻¹, more preferably greater than 10⁵ cm⁻¹.

In at least some of the embodiments disclosed herein, the SAM may be any material that absorbs light emitted inside an OLED stack and/or absorbs ambient light that enters the device that includes the OLED stack. The amount of absorption of light may be at least 1%, 3%, 5%, 10%, at least 15%, or the like.

In an embodiment, the SAM may have a Stokes shift of less than 100 nm. In some embodiments described herein, the SAM may be absorbing light, but may not be emitting light and thus the SAM may not have a Stokes shift. Instead, the SAM may absorb the OLED light and then transfer the energy (via Förster resonant energy transfer (FRET), or Dexter electron transfer (DET)), plasmon coupling, or any other energy transfer mechanism to another emitter. In some embodiments, the device may include one material for absorption and one material for emission, where the materials may overlap their absorption and emission spectra. In these embodiments, the two materials may be selected to have the peak absorption wavelength of one material aligned exactly, or with some other predefined shift, to the peak emission wavelength of the other material, rather than relying on a single material to have a Stokes shift. In an embodiment, the one material for absorption and one material for emission may be found in the SAL. In an embodiment, the SAL may include a first SAL layer that includes the one material for absorption and a second SAL layer that includes the one material for emission. In an embodiment, the SAL may include a first SAL layer that includes both the one material for absorption and the one material for emission mixed within the first SAL layer.

In some embodiments described herein, the SAM may be disposed between electrodes. In some embodiments, the SAM may contribute 0.1% to 100% of the energy that is transferred into the surface plasmon mode, which may not occur for other absorbing structures. The plasmons may be the collective oscillation of electron density in a metal, relative to the fixed positive ions. This oscillation may occur when an electric field is applied to a metal, which may cause the electrons to move to a first side, uncovering positive ions on a second side. When the electric field is removed, or reversed in direction, the electrons may move back to the first side or may oscillate back and forth when an oscillating electric field is applied. The surface plasmons may be coherent electron oscillations that are restricted to a metal surface or a metal dielectric interface. When the surface plasmon couples with the photons, the interaction with the electromagnetic energy may result in a quasiparticle, or an excitation mode called surface plasmon polariton, which may propagate along the metal surface or metal-dielectric interface.

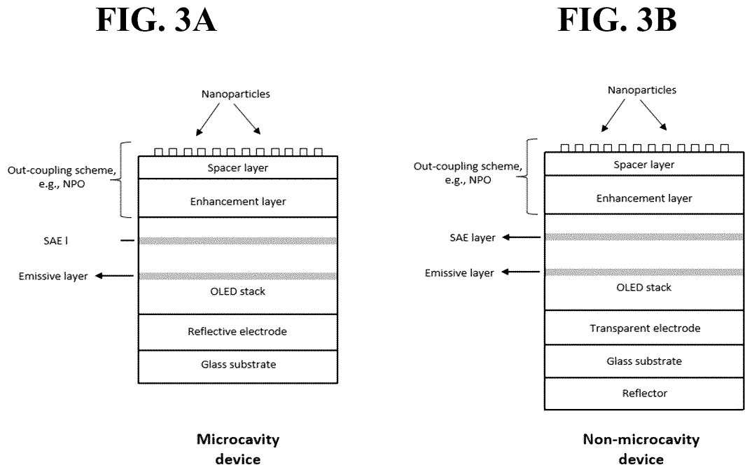

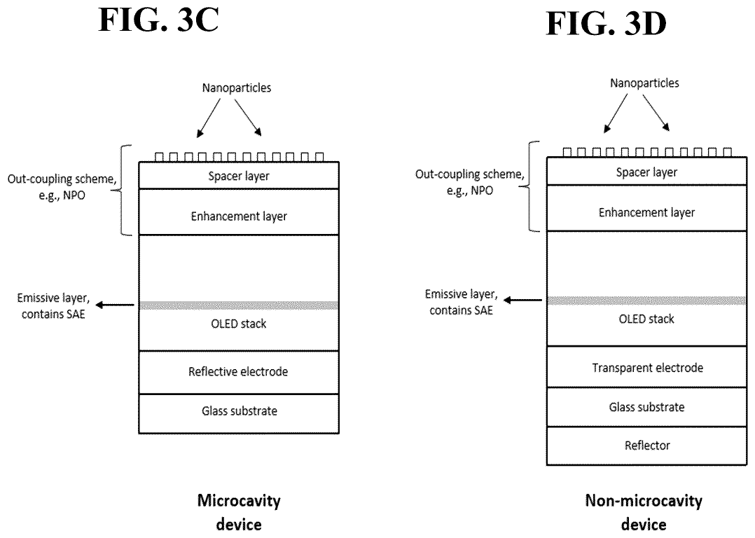

The device architecture in embodiments of the disclosed subject matter may include a reflecting layer, which comprises a metal or dielectric material or some combination thereof, that reflects non-plasmon-coupled light back toward the SAL for reabsorption. The reflecting layer may be placed to establish a microcavity (e.g., as shown in FIG. 3A), which means that the location of the layer results in coherent reflection of light. This may be tuned to resonate near the emission wavelength, specifically detuned away from the emission wavelength (for example, an antinode of the cavity), or tuned to the wavelength of peak absorption for the SAM and/or SAL. In other embodiments, the reflecting layer may be placed far enough away from the emission source to avoid a microcavity, resulting in an incoherent reflection, and may utilize far-field mirror-like reflection (e.g., as shown in FIG. 3B). Once the photons are directed back toward the SAL, they can be reabsorbed by the SAM and those excitons may have another chance to couple into the plasmon mode. This process of reabsorption by the SAM to produce excitons and then either coupling into the plasmon mode or coupling to the emission from the SAM may repeat until virtually all the excited state energy is transferred into the plasmon mode.

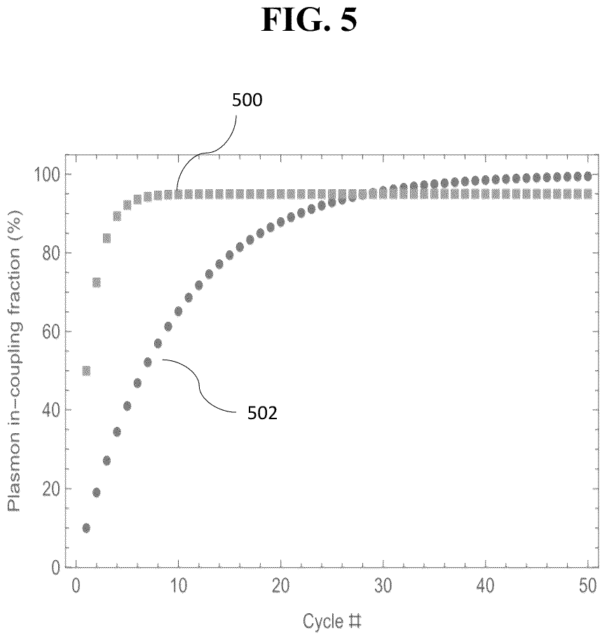

To reduce losses, the emitter in the SAM process may have a high photoluminescent quantum yield (PLQY) and the absorbing material may have a large extinction coefficient. In some embodiments, the emitter may be both the absorbing and emitting material. Thus, the emitter may have strong self-absorption. For strong self-absorption, there may be little Stokes shift between the absorption and emission peaks and/or significant tail overlap between the emitter's absorption and emission spectra. As an example, for a strongly self-absorbing emitter with unity PLQY and a 50% plasmon in-coupling efficiency, it may take 7 emission/reabsorption cycles to achieve greater than 99% plasmon in-coupling efficiency: (1) 50% excitation of SPPs and 50% photon generation; (2) the remaining 50% photons reabsorb to form excitons and another 50% of those form SPPs, increasing the SPP fraction to a total of 75% after including the incoupling from step 1; (3) process (2) may be repeated, increasing the SPP fraction to 87.5%; then (4) 93.75%; then (5) 96.875%; then (6) about 98.5%; then (7) greater than 99%. This is shown by line 500 in FIG. 5. For an SAE with 90% PLQY and 50% plasmon in-coupling efficiency (i.e., a Purcell factor of 2), the plasmon in-coupling may converge to 95% in-coupling within 11 cycles. As long as the PLQY is near unity, the plasmon in-coupling can be low and may still result in near-unity plasmon in-coupling after a number of cycles. For example, an SAE with unity PLQY and 10% plasmon in-coupling efficiency may still converge to greater than 99% plasmon in-coupling after 45 cycles, as shown by line 502 in FIG. 5. These example calculations assume that every photon incident on the SAE may be absorbed and generate an exciton. For SAEs where the absorption strength (or extinction coefficient) does not result in unity photon absorption, the number of cycles may correspondingly increase. For example, if it takes an average of 2 interactions with a photon to result in an absorption event, the calculated number of cycles above may double. If it takes an average of 10 interactions with a photon to result in an absorption event, the number of cycles may increase by an order of magnitude. The maximum in-coupling fraction that may be obtained for a given number of cycles is given by the relation:

$$In - coupling = 100 \cdot in [ 1 + PLQY \cdot \sum {( 1 - in )}^{a} ] , in percent$$

Where in is the in-coupling fraction and the sum occurs over all α from α=1 to the number of cycles after the first electrically-excited emission event. The in-coupling fraction after the first electrically-excited emission event may be the in-coupling fraction itself. As the number of cycles approaches infinity, the geometric series may converge, and the relation reduces to:

$$Max in - coupling = 100 \cdot in [ 1 + PLQY ( 1 / in - 1 ) ] , in percent$$

If either the in-coupling fraction or the PLQY is unity, then the max in-coupling fraction may be unity. For a 90% PLQY emitter with 50% in-coupling, the maximum in-coupling fraction may be 95%. For an 80% PLQY emitter with 20% in-coupling, the maximum in-coupling fraction may be 84%.

In another preferred embodiment, the SAM may be a host that absorbs the light generated by the emitter. In this embodiment, as long as the host has enough energy difference between the singlet of the host and the final emitter to drive excitons to the emitter, preferably greater than 0.02 eV, the process may still work. Förster resonant energy transfer (FRET) may be driven by spectral overlap. The overlap integral is related to the extinction coefficient, which has units of M⁻¹ cm⁻¹. The overlap integral itself (i.e., the overlap between the donor emission and the acceptor absorption spectra) is in units of M⁻¹ cm⁻¹ nm⁴. In some embodiments, the overlap integral may have a range of 10⁹ to 10¹⁶ M⁻¹ cm⁻¹ nm⁴, or more preferably have a range of 10¹⁰ to 10¹⁵ M⁻¹ cm⁻¹ nm⁴.

For a plasmonic OLED, the external quantum efficiency (EQE), assuming unity internal quantum efficiency, may be equal to the product of plasmon in-coupling efficiency and plasmon out-coupling efficiency. With this method, plasmon in-coupling efficiency may approach 100%. This means that EQE may approach the plasmon out-coupling efficiency, which may be more than 60% or even 80%.

The device in embodiments of the disclosed subject matter may include one or more emitters, and each emitter may be, but is not limited to, a phosphor, a fluorophore, a thermally activated delayed fluorescence emitter (TADF), a perovskite, including nanosized perovskite materials, and/or a quantum dot. The self-absorbing emitter may be electrically excited, and/or may exist in the device stack only to be optically pumped by the non-plasmon-coupled emission of a separate electrically excited emitter in another or the same layer. Examples of this arrangement are shown in FIGS. 3A-3D. This can be advantageous for several reasons. For an SAE in a separate, non-electrically pumped layer where no excitons are expected to be formed from charge recombination, there may be no need to design the SAE molecule to be stable against charge or excited states, including stable to triplet excited states, since the SAE excitons may be optically pumped and therefore separated from both charge and excited states in the EML. In the case where the SAE is disposed in a transport layer, blocking layer, or injection layer, there still may be charge near the SAE. In this case, it may be preferable to design the energy levels of the SAE to minimize the likelihood of charge on the molecule, or only a specific charge. For example, a SAE material that is deposited in the ETL may only need to be designed to be stable to electrons, as no holes would be expected to be present within the ETL. Still, it may be possible for charge to be located on the molecule, but only one sign of charge (i.e., either an electron or hole, but not both). Further, the SAE molecule may only need to match one energy level, for example, the lowest unoccupied molecular orbital (LUMO) if located in an electron transporting layer (ETL), or the highest occupied molecular orbital (HOMO) if located in a hole transporting layer (HTL). Thus, the molecular design of the SAE may be simplified, and properties such as high PLQY, strong self-absorption, and/or a high extinction coefficient may be prioritized. In one example embodiment, the EML may be electrically pumped, and the non-plasmon-coupled emission may excite the SAE, which then couples some fraction of energy into the plasmon mode. The non-plasmon-coupled emission may reflect off the reflecting layer, and may be reabsorbed by the SAE. This process may repeat until unity plasmon coupling is achieved.

The SAE may be located in any device layer, such as a transport layer, blocking layer, injection layer, an emissive layer, a capping layer, and/or some other layer not between the two electrodes (i.e., cathode and anode) of the device. The SAE may be doped into a host material, which may or may not also absorb the emission, or may exist as a neat layer. Some SAEs may increase their self-absorption strength when aggregated, so high concentration or neat layers may be desired.

It is not uncommon for plasmonic OLEDs to incorporate device stack layers that are thinner than in conventional OLED design. Often, the EML and/or a transport layer will be thin, such as less than 50 nm thick, more preferably less than 30 nm thick, and most preferably less than 20 nm thick to locate the excited state energy close to the enhancement layer. However, for an OLED with an SAE, even a plasmon in-coupling efficiency of less than 10% per excitation event of the SAE molecule may result in nearly unity plasmon in-coupling within about 50 emission/reabsorption cycles, provided the SAE has unity PLQY and that every photon is absorbed to create an exciton. In a preferred embodiment, is the SAE may be located within enough proximity to the enhancement layer to facilitate at least a modest coupling to the plasmon mode. For example, the SAE layer may be spaced less than 1000 nm away from the enhancement layer, less than 500 nm, less than 250 nm, less than 150 nm, more preferably less than 100 nm away, most preferably less than 50 nm away. For devices in embodiments of the disclosed subject matter where the SAE is not located in the EML, the EML and transport layers may be any desired thickness, including conventional bottom- or top-emission configuration thicknesses, which may be typically 30-50 nm for the EML, and 20 nm to 200 nm for the HTL and/or ETL. This may circumvent the well-known OLED stability penalty for thin EMLs. Moreover, the lack of rigid requirements for cavity and/or device stack tuning improves the manufacturability of the arrangements of the disclosed subject matter, especially in tandem and microcavity structures, as greater tolerances in layer thickness variation across the substrate may be acceptable. The ability of the devices of the disclosed subject matter to utilize thinner layers may enable a reduction in operating voltage and hence provide increased power efficiency.

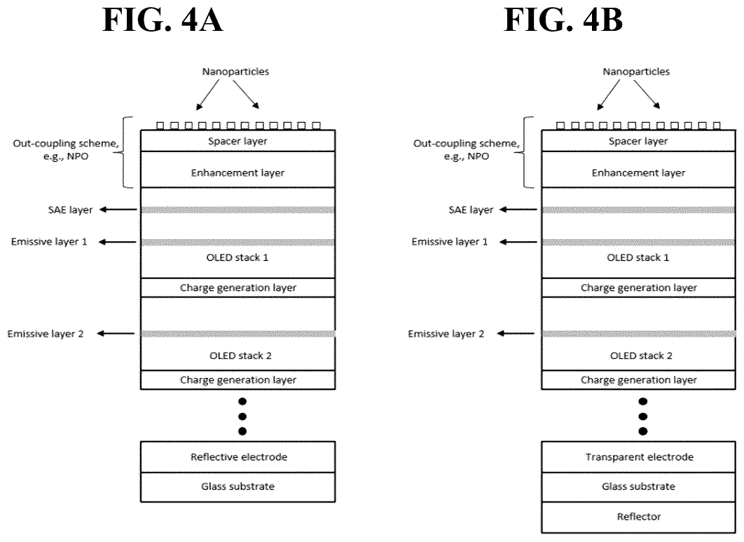

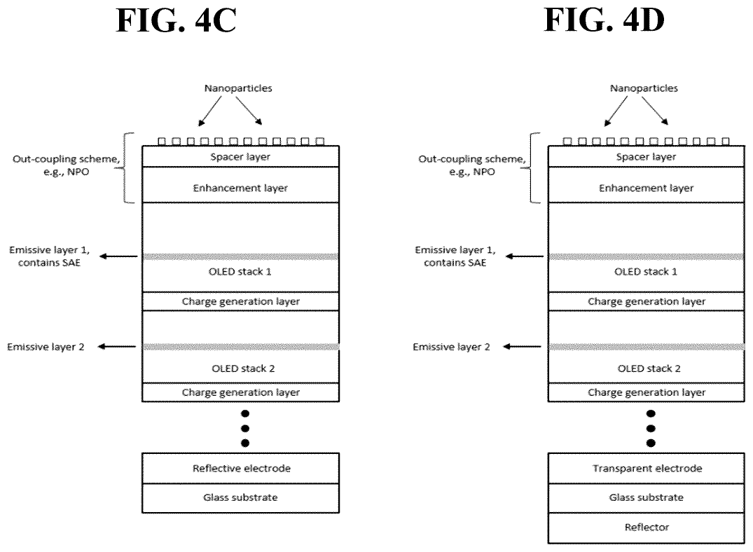

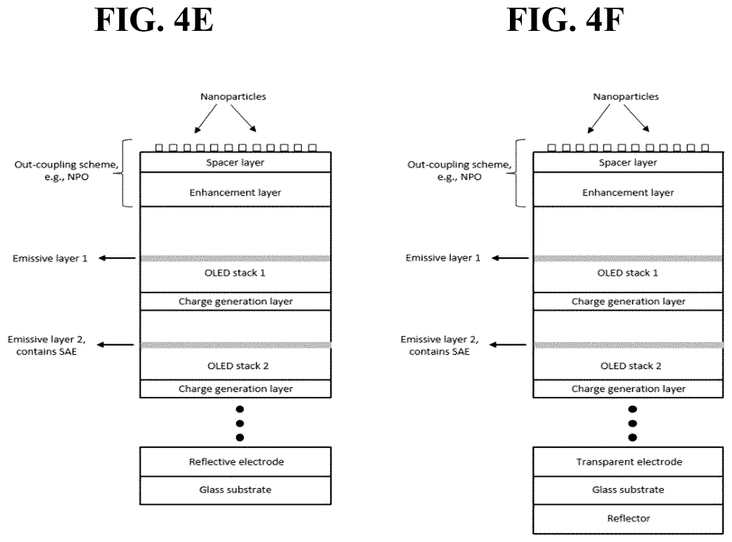

The device arrangements in the embodiments of the disclosed subject matter may be compatible with stacked or tandem OLEDs. In these devices, the light generated by the tandem OLED stack may be trapped inside the device, due to the opaque reflecting layer and mostly-opaque enhancement layer with typical transmittance of less than 40%, more typically less than 25%, or even 10% over the visible range. The trapped light, if not directly absorbed by an SAE, may be absorbed by a SAL and transferred to the emitter or SAE, at which point the energy may be coupled into the plasmon mode (with a cumulative efficiency that can approach unity, as discussed previously) and subsequently converted to light through an out-coupling scheme. The outcoupling scheme may be, for example, an outcoupling layer comprising nanoparticles, grating, corrugated surface, or any number of other configurations demonstrated to out-couple plasmons into light. Since the number of photons generated inside the device may increase with the number of stacks in the tandem device, the EQE of the OLED may be high, and may even exceed 100%. It is predicted that each subunit may contribute an EQE equal to the out-coupling efficiency of the plasmon out-coupling mechanism. For example, a three-stack tandem OLED incorporating the architecture of the embodiments of the disclosed subject matter and a plasmon out-coupling efficiency of 60% may have an expected EQE of 180%. Since the device may have efficiency beyond what is possible with conventional tandem architectures, the devices of the disclosed subject matter may realize even greater operational stability improvements than conventional tandem OLEDs. Further, since the tandem stack layer thicknesses do not need to be chosen to maximize conventional photon out-coupling efficiency, thinner layers may be used which could have the effect of decreasing operating voltage and improving power efficiency. This may improve manufacturability by eliminating rigid requirements on the device cavity, allowing freedom to vary layer thicknesses without penalizing device performance or affecting emission properties, such as color and intensity shift vs. angle, since those properties are largely set by the plasmon out-coupling scheme. These device structures would also be more tolerant of variation in layer thicknesses across the panel of a display. For example, if the HTL of the device varied by 10% across a 13″ display, the impact on overall device performance may be minimal. Even if the distance from the SAM layer to the enhancement layer varied by 10%, the expected change in Purcell is less than 5%, thus having a negligible impact on the number of reabsorption events required to achieve the maximum in-coupling. Further, the plasmon out-coupling scheme may be designed to reduce ambient light reflection, such as a nanoparticle-based out-coupling scheme that scatters ambient light diffusely, thereby improving manufacturability at the panel level by reducing the need for polarizers and/or other methods to reduce ambient light reflection. In a preferred embodiment, there may be only one SAE layer in a tandem device, as shown in FIGS. 4A-4F. In some embodiment, multiple SAE layers may be preferable. The tandem device may either incorporate a microcavity as shown in FIG. 4A, or be without a microcavity, as shown in FIG. 4B.

The SAM and/or SAE inside the device may serve to reduce ambient light reflection off the OLED active area. Since photoexcitation of the SAM(s) in the device may create excitons that subsequently couple into the plasmon and get scattered out as photons, ambient light may serve to increase the brightness of the OLED pixels. This may be advantageous especially in outdoor conditions where competition with bright ambient sunlight necessitates brighter OLED pixels. To maintain high contrast ratio, pixels in the “off” state may be reverse biased.

There are several advantages of the architectures of the embodiments of the disclosed subject matter over that of conventional single-stack or tandem devices. For example, a device incorporating an outcoupling layer with nanoparticles on the top side of the OLED may achieve a Lambertian emission profile with less color shift versus angle than conventional top-emitting OLEDs. For devices with large cavities, like tandem OLEDs, the complexity of the cavity design may be reduced since the photons may not be emitted to free space from the cavity but may be first absorbed by the SAE and pass through the plasmon mode.

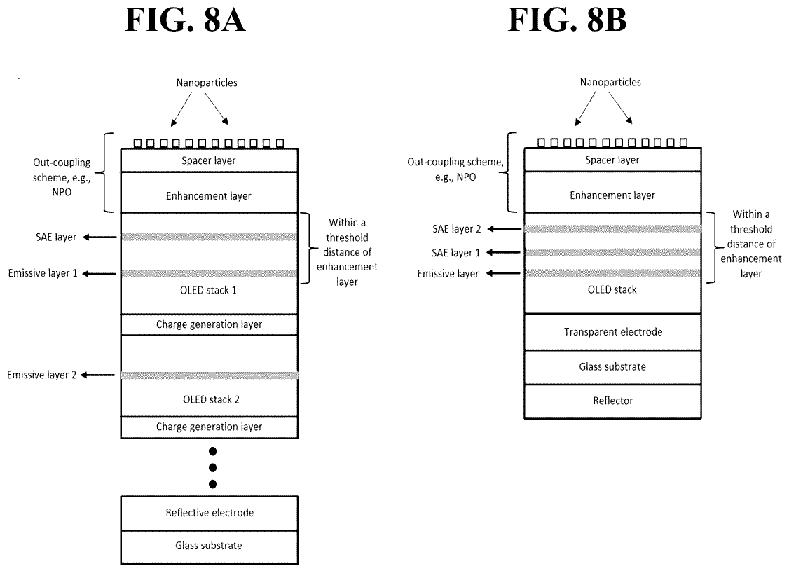

In some embodiments, it may be preferable to position the EML and/or SAM/SAE layer(s) within a threshold distance of the enhancement layer, which may reduce the excited state transient lifetime and lead to more stable devices, such as shown in the example embodiment of FIG. 8B. In the case of a tandem stack, at least one of either the EML(s) and/or SAM/SAE layer(s) may be within a threshold distance of the enhancement layer, such as shown in the example embodiment of FIG. 8A. Further, the device stability may be improved by adjusting the thickness of the EML(s) independently of the SAE layer. Thickening the EML typically increases device stability by increasing the volume that excitons may occupy, thereby decreasing the likelihood of destabilizing excited state interactions. The benefit of the architectures of the disclosed subject matter is that device stability may be increased by adjusting the EML thickness without having to worry about matching optical out-coupling nodes or shifting the color of the device as would normally be required for a conventional device that emits light out of the OLED stack directly.

The transition dipole moments (TDM) of the SAE and emitter may be chosen to meet a variety of desired conditions. For an SAE inside the EML with another emitter, it may be desirable to align both TDMs preferentially both horizontally or both vertically to enhance the energy transfer efficiency to the SAE, which may occur via far field photon emission and reabsorption, or non-radiative energy transfer like Förster resonant energy transfer (FRET), or Dexter electron transfer (DET). In one preferred embodiment, where the SAE may be located in a layer separate from the EML, it may be preferable to align the TDM of the emitter in the EML horizontally in order to have the photons bounce off the reflecting layer at close to normal incidence and then be reabsorbed by the SAE. In another preferred embodiment, the TDM of the emitter in the EML may be vertically oriented so that it efficiently couples photons into a waveguided mode that can then be absorbed by the SAE. In another preferred embodiment, the SAE may be vertically oriented to have increased plasmon coupling efficiency. Depending on the wavelength of the light emitted from the organic emissive material, the ideal far-field plasmon coupling occurs when the photon is incident upon the enhancement layer at 39-45 degrees, relative to the plane of the enhancement layer. This corresponds to a VDR of 0.33-0.65 for the organic emissive material.

The architectures of the disclosed subject matter may be compatible with sensitized OLEDs, where excited state energy may be transferred from a sensitizer to an emitter. The SAE may be located in the sensitized EML or in a separate layer, and may be used to increase the efficiency of the device. In one embodiment, the emitter in the EML may act as the “sensitizer” and the SAE may act as the “acceptor.” Locating the SAE in a layer separate from the EML may provide a benefit over traditional sensitized devices in that there may be no energy transfer loss via DET as the two emissive species may be separated over a larger distance than DET can occur.

The SAE may be arranged to have a narrow-line shape for improved color purity. The SAE may be arranged to achieve strong spectral overlap with the resonance of the plasmon out-coupling scheme for high out-coupling efficiency. The out-coupling scheme may be designed to customize the emission profile, especially the color shift versus angle and intensity versus angle. In the case of an outcoupling layer with nanoparticles, the nanoparticles may be arranged in random, quasiperiodic, or ordered arrays, with spectral overlap either tuned to or detuned from the SAE emission to modify the emission and angular profile.

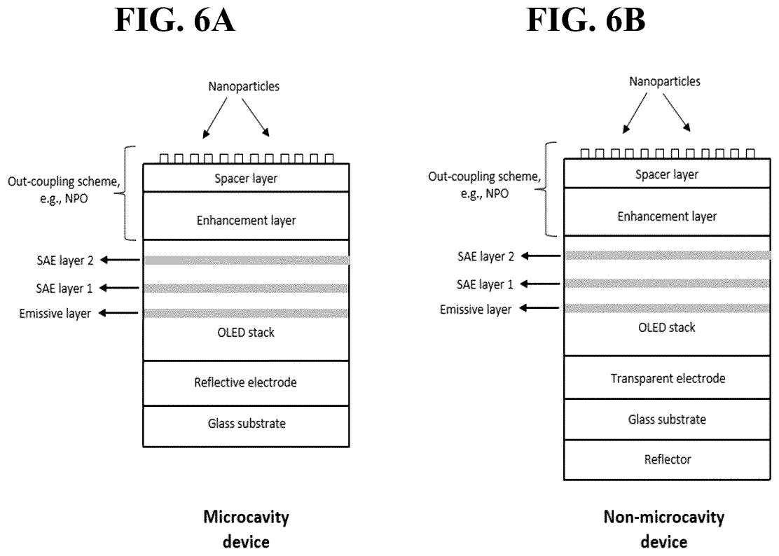

The device may incorporate one or more SAEs in either the same or different layers, as shown, for example, the arrangements of FIGS. 6A-6B. This may be desirable to incorporate the benefits of different SAE properties. In one example embodiment, one SAE in a layer farther from the enhancement layer may be configured with a horizontally-aligned TDM in order to bounce emitted light at close to normal incidence off the reflecting layer to reduce waveguiding and “redirect” waveguided light (through absorption and re-emission) at an angle more perpendicular to the substrate, while a second SAE closer to the enhancement layer may have a more vertically-aligned TDM to improve plasmon coupling efficiency.

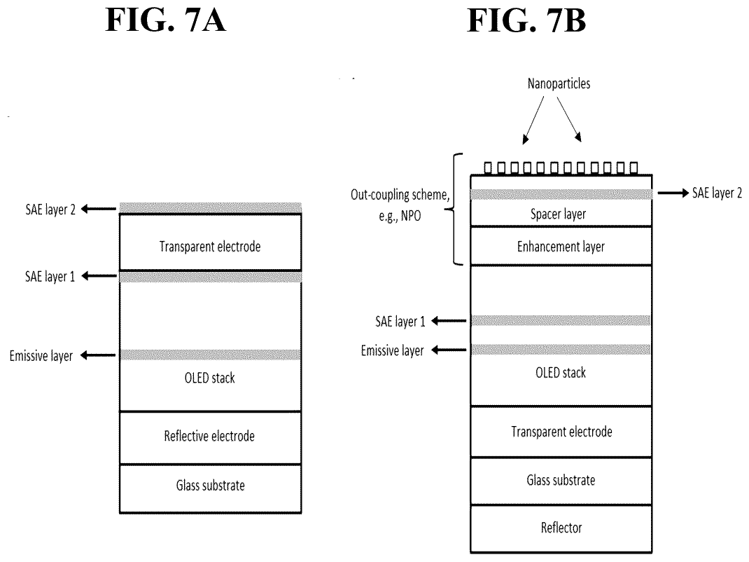

In one embodiment, one or more of the SAE layers may not be located between the device electrodes. For example, as shown in FIG. 7A, there may be two SAE layers, one of which sits atop a transparent electrode. In this example embodiment, SAE layer 1 may have a horizontal TDM (i.e., a vertical dipole ratio (VDR) less than 0.33, less than 0.25 or less than 0.2) to redirect waveguided light efficiently through the transparent electrode to excite SAE layer 2. SAE layer 2 may emit the light into air. SAE layer 2 may be excited by the evanescent waves formed at the electrode/air interface due to the waveguided light from SAE layer 1. To increase the photon-to-air extraction efficiency, SAE layer 2 may be made very thin, preferably less than 10 nm, more preferably less than 5 nm, and most preferably less than 1 nm. In the case where the distance between SAE layer 1 and SAE layer 2 is small, preferably less than 20 nm, more preferably less than 10 nm, and most preferably less than 5 nm, the energy transfer between SAE layer 1 and SAE layer 2 may be maximized. When there is less than 5 nm of separation, Förster resonant energy transfer (FRET) may aid in energy transfer between the SAE layers. In FIG. 7B, SAE layer 2 may be located in the spacer layer as part of the plasmon-to-photon outcoupling structure. This may improve the plasmon-to-photon conversion efficiency as SAE layer 2 may be pumped by the enhancement layer and may be subject to large electric fields, and hence increased Purcell effects, in the spacer layer region.

There may be five preferred embodiments where the emitter acts as the SAM. A first example embodiment may have an electrically-pumped phosphor in EML, and an optically-pumped SAE in a separate layer. A second example embodiment may have an electrically-pumped TADF in EML, and an optically-pumped SAE in a separate layer. A third example embodiment may have an electrically-pumped TADF in an EML that is also the SAE. A fourth example embodiment may have an electrically-pumped fluorophore in EML, and an optically-pumped SAE in a separate layer. A fifth example embodiment may have an electrically-pumped fluorophore in an EML that is also the SAE.

There may be five preferred embodiments where the host acts as the SAM. A first example embodiment may include an electrically-pumped phosphor in EML, and an optically-pumped SAM host that may transfer energy to emitter in separate layer. A second example embodiment may include an electrically-pumped TADF in EML, and an optically-pumped SAM host transfers energy to emitter in separate layer. A third example embodiment may include an electrically-pumped TADF in an EML that is doped into a SAM host. A fourth example embodiment may include an electrically-pumped fluorophore in EML, and an optically-pumped SAM host that may transfer energy to emitter in separate layer. A fifth example embodiment may include an electrically-pumped fluorophore in EML that is doped into a SAM host.

In embodiments without an enhancement layer, reabsorption may lead to re-emission of the photons to the light escape cone, possibly leading to increased OLED efficiency. In one example embodiment, waveguided light may be reabsorbed by an SAE (or SAM host that transfers the energy to an emitter) wherein the SAE (or emitter) may have a preferentially horizontally oriented TDM.

As shown in FIGS. 3A-8B described above, a device of the disclosed subject matter may include a substrate, a first electrode disposed over the substrate, and a first organic emissive layer (EML) disposed over the first electrode, with the first EML including a first emissive material. A second electrode may be disposed over the first EML. An enhancement layer may include a plasmonic material that exhibits surface plasmon resonance that non-radiatively couples to the first emissive material. A first SAM may be disposed over the substrate, where the first SAM may include a material that absorbs at least a portion of light emitted by the first EML.

In some embodiments, the second electrode may comprise an enhancement layer, where the enhancement layer comprises a plasmonic material that exhibits surface plasmon resonance that couples to the first emissive material.

In some embodiments, the plasmonic material may be capable of transferring excited state energy from the first emissive material to a surface plasmon polariton of the enhancement layer. The SAM may be capable of emitting light, coupling energy into a plasmon mode, and/or transferring energy to another material.

In some embodiments, the first EML of the device may include the first SAM. In other embodiments, the first emissive material of the device may be the first SAM.

The first electrode of the device may be a reflective electrode, and the first SAM may be disposed over the first EML or within the first EML. In some embodiments, the first electrode and the second electrode may form a microcavity structure tuned for an emission spectrum of the emissive material. In other embodiments, the first electrode and the second electrode may form a microcavity structure that is detuned away from the emission of wavelengths by an emitter in the microcavity.

The first electrode of the device may be a transparent electrode, and the first SAM may be disposed over the first EML or within the first EML as shown, for example, in FIGS. 3B and 3D. The device may further include a reflector disposed on a side of the substrate that is opposite to the first electrode. The reflector may be disposed at least 10 μm away from the first EML.

In some embodiments, the SAM need not be a threshold distance enhancement layer to achieve a high plasmon in-coupling fraction.

The device may include an outcoupling layer disposed over the first SAM. The outcoupling layer may include a plasmon-to-photon outcoupling layer. The outcoupling layer of the device may include the enhancement layer, and a plurality of nanoparticles disposed over the enhancement layer.

In some embodiments, a photoluminescent quantum yield (PLQY) of the SAM of the device may be at least 80%. In some embodiments where the SAM is the host, the PLQY may be near zero. A relationship between a radiative rate (kR) and a non-radiative rate (kNR) of the first SAM or the first EML of the device may be kR≥4*kNR.

The device may include a second SAM disposed over the second electrode, as shown, for example, in FIGS. 7A-7B. In some embodiments, there may be transparent top electrode, so the device may not have a microcavity. In some embodiments, the top electrode may be reflective and the device may have a microcavity. Although the device of FIG. 7B may not have a microcavity as the reflector is too far away. If this arrangement were modified to have a microcavity, the microcavity may be detuned.

The first and second electrodes may form a microcavity structure tuned for an emission spectrum of the emissive material. The first emissive layer of the device may be part of a first organic light emitting diode (OLED) stack, and may include a second emissive layer that may be part of a second OLED stack, where the first emissive layer is closer to the enhancement layer than the second emissive layer, where the first emissive layer is within a threshold distance. The first emissive material may have a total non-radiative decay rate constant

$${k}_{non - rad}^{0} ,$$

a total radiative decay rate constant

$${k}_{rad}^{0} ,$$

a total non-radiative decay rate constant due to the enhancement layer

$${k}_{non - rad}^{plasmon} ,$$

and a total radiative decay rate constant due to the enhancement layer

$${k}_{rad}^{plasmon} ,$$

where the enhancement layer may be disposed not more than the threshold distance from the first emissive material, and where the threshold distance is a distance at which

$$\frac{{k}_{rad}^{plasmon}}{{k}_{non - rad}^{plasmon}} = \frac{{k}_{rad}^{0}}{{k}_{non - rad}^{0}} .$$

In some embodiments, the device may include a charge generation layer disposed over the first EML, and a second EML disposed above the charge generation layer, the second EML may include a second emissive material, such as shown in FIGS. 4A-4B. In some embodiments, the first EML of the device may include the SAM, and in another embodiment, the second EML of the device may include the SAM. At least two of the first electrode, the second electrode, and the charge generation layer may form a microcavity structure tuned or detuned for an emission spectrum of the first emissive material and/or the second emissive material (see, e.g., FIGS. 4A, 4C, and 4E).

The device may include a second SAM disposed over the first SAM and between the first electrode and the second electrode, as shown, for example, in FIGS. 6A-6B. The first and second electrodes may form a microcavity structure tuned or detuned for an emission spectrum of the emissive material, as shown, for example, in FIG. 6A.

In some embodiments, the material of the first SAM of the device may absorb at least 1%, 5%, 10%, 25%, 50%, and up to 100% of light emitted by the EML. The material of the first SAM of the device may absorb greater than 0.3%, greater than 1%, greater than 3%, greater than 5%, greater than 10%, greater than 20%, greater than 50%, and/or greater than 90% of light emitted by the EML. That is, the material of the SAM may absorb a non-zero amount of light emitted by the EML each time a photon interacts with the material.

In some embodiments, the SAM of the device may have at least one property of: a Stoke's shift between the absorption and emission spectra of the SAM of less than or equal to 100 nm; an extinction coefficient of a highest absorption band of the SAM that is greater than or equal to 103 M⁻¹·cm⁻¹; a poly-carbo or heterocyclic ring system comprising at least two fused rings; the SAM is doped at a concentration of greater than or equal to 0.5% by volume; the SAM is doped uniformly into the first EML and is capable of accepting energy transferred from one or more of the components of the first EML; the SAM is doped at an interface between the first EML and a blocking layer (BL) interface and is capable of accepting energy transferred from one or more of the components of the first EML or of the BL; and/o the SAM is doped into an electron transport layer (ETL) and is capable of accepting energy transferred from one or more of the components of the ETL.

In some embodiments, the first electrode of the device may comprise an enhancement layer, the second electrode may comprise an enhancement layer, and/or the device may comprise an enhancement layer disposed over the second electrode.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device comprising:
a substrate;
a first electrode disposed over the substrate;
a first organic emissive layer (EML) disposed over the first electrode, the first EML comprising a first emissive material;
a second electrode disposed over the first EML; and
a first self-absorbing material (SAM) disposed in a stack with the substrate, the first SAM comprising a material that transfers at least a portion of the energy from the first EML to the first SAM.

2. The device of claim 1, wherein the second electrode comprises an enhancement layer, and wherein the enhancement layer comprises a plasmonic material that exhibits surface plasmon resonance that couples to the first emissive material.

3. The device of claim 2, wherein the plasmonic material is capable of transferring excited state energy from the first emissive material to a non-radiative mode of a surface plasmon polariton of the enhancement layer.

4. The device of claim 2, wherein the plasmonic material is capable of transferring excited state energy non-radiatively or radiatively.

5. The device of claim 2, wherein the SAM is capable of at least one selected from a group consisting of: emitting light, coupling energy into a plasmon mode of the enhancement layer of the device, and transferring energy to another material.

6. The device of claim 2, further comprising:
an outcoupling layer disposed over the first SAM.

7. (canceled)

8. (canceled)

9. (canceled)

10. (canceled)

11. (canceled)

12. (canceled)

13. The device of claim 1, wherein the first EML comprises the first SAM.

14. The device of claim 13, wherein the first emissive material is the first SAM.

15. (canceled)

16. (canceled)

17. (canceled)

18. The device of claim 1, wherein the first electrode is a transparent electrode and the first SAM is disposed over the first EML or within the first EML.

19. The device of claim 18, further comprising a reflector disposed on a side of the substrate that is opposite to the first electrode.

20. The device of claim 19, wherein the reflector is disposed at least 10 μm away from the first EML.

21. The device of claim 20, wherein the first SAM is disposed between the reflector and the substrate.

22. (canceled)

23. The device of claim 1, wherein a photoluminescent quantum yield (PLQY) of the first SAM is at least 80%.

24. (canceled)

25. (canceled)

26. (canceled)

27. (canceled)

28. (canceled)

29. The device of claim 1, further comprising a second SAM disposed over the first SAM and between the first electrode and the second electrode.

30. (canceled)

31. The device of claim 1, wherein the material of the first SAM absorbs at least 1%, 5%, 10%, 25%, 50%, or up to 100% of light emitted by the EML.

32. The device of claim 1, wherein the material of the first SAM of the device absorbs at least one selected from a group consisting of: greater than 0.3%, greater than 1%, greater than 3%, greater than 5%, greater than 10%, greater than 20%, greater than 50%, and greater than 90% of light emitted by the EML.

33. The device of claim 1, wherein the SAM has at least one property selected from a group consisting of: a Stoke's shift between the absorption and emission spectra of the SAM of less than or equal to 100 nm; an extinction coefficient of a highest absorption band of the SAM that is greater than or equal to 10³ M⁻¹·cm⁻¹; a poly-carbo or heterocyclic ring system comprising at least two fused rings; the SAM is doped at a concentration of greater than or equal to 0.5% by volume; the SAM is doped uniformly into the first EML and is capable of accepting energy transferred from one or more of the components of the first EML; the SAM is doped at an interface between the first EML and a blocking layer (BL) interface and is capable of accepting energy transferred from one or more of the components of the first EML or of the BL; and the SAM is doped into an electron transport layer (ETL) and is capable of accepting energy transferred from one or more of the components of the ETL.

34. The device of claim 1, wherein the first SAM comprises a self-absorbing emitter (SAE) layer that has a vertical dipole ratio (VDR) of at least one selected from a group consisting of: less than 0.33, less than 0.25, and less than 0.2.

35. (canceled)

36. A consumer electronic device comprising the device of claim 1.

37. The consumer electronic device of claim 36, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, optical communication device, and a sign.
